(19) United States
(12) Patent Application Publication
(10) Pub. No.: US 2016/0274428 A1
(43) Pub. Date: Sep. 22, 2016

(54) DISPLAY DEVICE AND METHOD OF MANUFACTURING THE SAME

(71) Applicant: SAMSUNG DISPLAY CO., LTD., Yongin-si, Gyeonggi-do (KR)

(72) Inventor: Swaehyun KIM, Asan-si (KR)

(21) Appl. No.: 14/983,095

(22) Filed: Dec. 29, 2015

(30) Foreign Application Priority Data
Mar. 17, 2015 (KR) 10-2015-0036630

(51) Int. Cl. G02F 1/1362; G02F 1/1339; H01L 27/12; G02F 1/1368

(52) U.S. Cl. CPC G02F 1/136209; G02F 1/1368; G02F 1/13394; H01L 27/124; H01L 27/1259; G02F 2001/136222; G02F 2001/136218

(57) ABSTRACT

A display device includes: a lower substrate including pixel regions and a light shielding area; an upper substrate opposed to the lower substrate; a liquid crystal layer between the lower substrate and the upper substrate; a gate line and a data line on the lower substrate; a thin film transistor connected to the gate line and the data line; color filters on the thin film transistor; and a pixel electrode on the color filters in the pixel region. The light shielding area may include a first light shielding area disposed with the gate line and the thin film transistor and a second light shielding area disposed with the data line; red and green color filters may be disposed in red and green pixel regions, respectively; and blue color filter may be disposed in blue pixel region and in the first light shielding area.

### CROSS-REFERENCE TO RELATED APPLICATION

This application claims priority to and the benefit of Korean Patent Application No. 10-2015-0036630, filed on Mar. 17, 2015, with the Korean Intellectual Property Office, the disclosure of which is incorporated herein in its entirety by reference.

### BACKGROUND

1. Field

Embodiments of the present inventive concept relate to a display device in which a color filter and a thin film transistor are disposed on the same substrate and to a method of manufacturing the display device.

2. Description of the Related Art

Display devices are classified into liquid crystal display (LCD) devices, organic light emitting diode (OLED) display devices, plasma display panel (PDP) devices, electrophoretic display (EPD) devices, and the like, based on a light emitting method thereof.

The LCD device includes two substrates opposed to each other, an electrode formed on the substrates, and a liquid crystal layer interposed between the substrates. Upon applying voltage to the electrodes, liquid crystal molecules of the liquid crystal layer are rearranged, such that an amount of transmitted light is adjusted in the display device.

An LCD device generally has a structure in which one of the two substrates includes a plurality of thin film transistors and a pixel electrode formed thereon and the other substrate includes a plurality of color filters, a light shielding member, and a common electrode formed thereon. In recent times, however, in order to prevent an alignment error between the pixel electrode and the color filter, a color filter on array (COA) structure has been suggested, in which a color filter, a light shielding member, a pixel electrode, and the like, in the absence of a common electrode, are formed on the same substrate.

Meanwhile, a thickness of liquid crystal layers inserted between two substrates is called a cell gap. The cell gap affects overall operation properties, such as a response time, a contrast ratio, a viewing angle, luminance uniformity, and the like.

Accordingly, when a display device does not have a uniform cell gap, an image may not be displayed uniformly over an entire screen, thereby causing an issue of deteriorated image quality.

Accordingly, in order to maintain a uniform cell gap over the entire area of the substrate, a plurality of column spacers are required on at least one of the two substrates. The column spacer may include a main column spacer configured to substantially support the two substrates and a sub-column spacer configured to assist the main column spacer.

Further, in order to simplify a process thereof, a structure of a black column spacer has been suggested, in which a shielding member and a column spacer are simultaneously formed. In such a case, the shielding member may include a column spacer and a peripheral portion, that is, a part other than the column spacer.

In order to obtain a suitable light shielding property to a predetermined extent, the light shielding member is required to have a thickness more than or equivalent to a predetermined thickness; however, there is a limitation, due to cell-gap limitation, on forming the shielding member to have a thickness more than a predetermined thickness.

Accordingly, a light shielding area may not sufficiently block light supplied from a backlight unit or may not suitably prevent externally incident light from being irradiated on a thin film transistor.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Aspects of embodiments of the present inventive concept are directed to a display device capable of improving a light shielding property in a light shielding area and a method of manufacturing the display device.

According to an exemplary embodiment of the present inventive concept, a display device includes: a lower substrate including red, green, and blue pixel regions and a light shielding area; an upper substrate opposed to the lower substrate; a liquid crystal layer between the lower substrate and the upper substrate; a gate line and a data line on the lower substrate; a thin film transistor connected to the gate line and the data line; red, green, and blue color filters on the thin film transistor; and a pixel electrode on the red, green, and blue color filters in the pixel region. The light shielding area may include a first light shielding area disposed with the gate line and the thin film transistor and a second light shielding area disposed with the data line; the red and green color filters may be disposed in the red and green pixel regions, respectively; and the blue color filter may be disposed in the blue pixel region and in the first light shielding area.

The display device may further include a light shielding member disposed on the blue color filter in the first light shielding area.

The light shielding member may include a column spacer and a peripheral portion, that is, a part other than the column spacer.

The display device may further include a shielding electrode disposed on the red, green, and blue color filters and overlapping the data line.

The shielding electrode may extend along the data line.

The blue color filter disposed on the thin film transistor may be directly in contact with the light shielding member.

The light shielding member disposed on the thin film transistor may have a thickness greater than a thickness of the light shielding member disposed on a peripheral portion of the thin film transistor.

According to an exemplary embodiment of the present inventive concept, a display device includes: a lower substrate including red, green, and blue pixel units; an upper substrate opposed to the lower substrate; a liquid crystal layer disposed between the lower substrate and the upper substrate; a gate line and a data line on the lower substrate; a thin film transistor connected to the gate line and the data line; red, green, and blue color filters on the thin film transistor; and a pixel electrode on the red, green, and blue color filters. Red, green, and blue pixel units may respectively include a pixel region disposed with the pixel electrode, a first light shielding area disposed with the gate line and the thin film transistor, and a second light shielding area disposed with the data line; the red and green color filters may be disposed on the red and green pixel units; and the blue color filter may be disposed on the blue pixel unit and in at least a part of each corresponding first light shielding area of the red and green pixel units.

The at least a part of each corresponding first light shielding area of the red and green pixel units may be disposed on the thin film transistor of the red and green pixel units.

The display device may further include a light shielding member disposed on the red, green, and blue color filters in the first light shielding area.

The light shielding member may include a column spacer and a peripheral portion, that is, a part other than the column spacer.

The display device may further include a shielding electrode disposed on the red, green, and blue color filters and overlapping the data line.

The shielding electrode may extend along the data line.

The blue color filter disposed on the thin film transistor may be directly in contact with the light shielding member.

The light shielding member disposed on the thin film transistor may have a thickness greater than a thickness of the light shielding member disposed on a peripheral portion of the thin film transistor.

According to an exemplary embodiment of the present inventive concept, a method of manufacturing a display device includes: forming a thin film transistor in a light shielding area corresponding to red, green, and blue pixel regions on a lower substrate; forming red and green color filters on the thin film transistor corresponding to the red and green pixel regions; forming a blue color filter on the thin film transistor in the blue pixel region and in the light shielding area in a light shielding area corresponding to red, green, and blue pixel regions; forming a planarization layer on the red, green, and blue color filters; and forming a light shielding member on the planarization layer in the light shielding area.

The forming of the light shielding member may further include forming a degassing hole on the planarization layer disposed on the thin film transistor.

The light shielding member disposed on the thin film transistor may have a thickness greater than a thickness of the light shielding member disposed on a peripheral portion of the thin film transistor.

The forming of the light shielding member may include simultaneously forming a column spacer and a pheripheral portion, that is, a part other than the column spacer, to each have different heights.

According to embodiments of the present inventive concept, a display device includes a blue color filter disposed on a light shielding area, thereby capable of improving a light shielding property in the light shielding area.

Further, according to embodiments of the present inventive concept, a display device includes a shielding member which is increased in thickness, the shielding member being disposed in the light shielding area, thereby capable of improving a light shielding property.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure of inventive concept will be more clearly understood from the following detailed description taken in conjunction with the accompanying drawings, in which:

FIG. 1 is a schematic plan view illustrating a display device according to an exemplary embodiment;

FIG. 2 is a schematic plan view illustrating color filters according to an exemplary embodiment;

FIG. 3 is a cross-sectional view taken along line I-I′ of FIG. 1;

FIG. 4 is a schematic plan view illustrating color filters according to another exemplary embodiment;

FIG. 5 is a schematic plan view illustrating a display device according to another exemplary embodiment;

FIG. 6 is a cross-sectional view taken along line II-II′ of FIG. 5; and

FIGS. 7A, 7B, 7C, 7D and 7E are cross-sectional views illustrating a method of manufacturing a display device according to another exemplary embodiment.

### DETAILED DESCRIPTION

Hereinafter, embodiments of the present disclosure of inventive concept will be described in more detail with reference to the accompanying drawings.

Although the present inventive concept can be modified in various manners and have several embodiments, specific embodiments are illustrated in the accompanying drawings and will be mainly described in the specification. However, the scope of the embodiments of the present inventive concept is not limited to the specific embodiments and should be construed as including all the changes, equivalents, and substitutions included in the spirit and scope of the present inventive concept.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

Some of the parts which are not associated with the description may not be provided in order to specifically describe embodiments of the present inventive concept, and like reference numerals refer to like elements throughout the specification.

In the drawings, certain elements or shapes may be simplified or exaggerated to better illustrate the present inventive concept, and other elements present in an actual product may also be omitted. Thus, the drawings are intended to facilitate the understanding of the present inventive concept.

Hereinafter, exemplary embodiments are described based on the assumption that a liquid crystal display (“LCD”) device is used as a display device according to the present inventive concept, but the inventive concepts are not limited thereto. Features of the inventive concept may be also applicable to an organic light emitting diode (“OLED”) display device.

In addition, a display device according to exemplary embodiments may have a color filter on array (COA) structure in which a thin film transistor and a color filter are disposed on the same substrate, and may have a black column spacer structure in which a black matrix and a column spacer are integrally formed into a single unit using the same material and process.

In addition, in a display device according to exemplary embodiments, a shielding member for shielding a data line against light may be omitted and an supplemental electrode wiring elongated parallel to the data line and overlap the data line may be provided to prevent light from being transmitted through a liquid crystal layer which is disposed around the data line. The liquid crystal layer is aligned not to transmit light by an electric field formed between the supplemental electrode and a common electrode, thereby preventing the visibility of the data line.

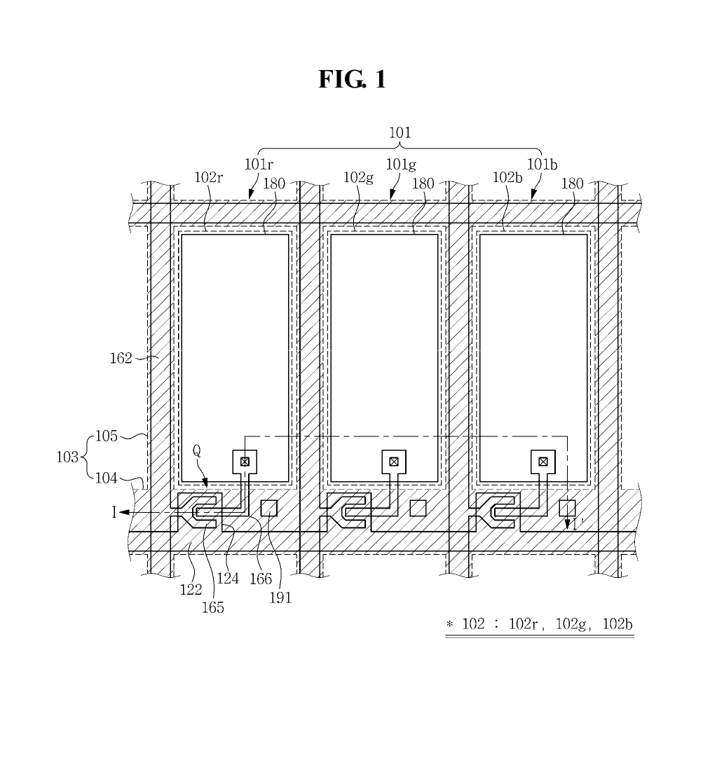

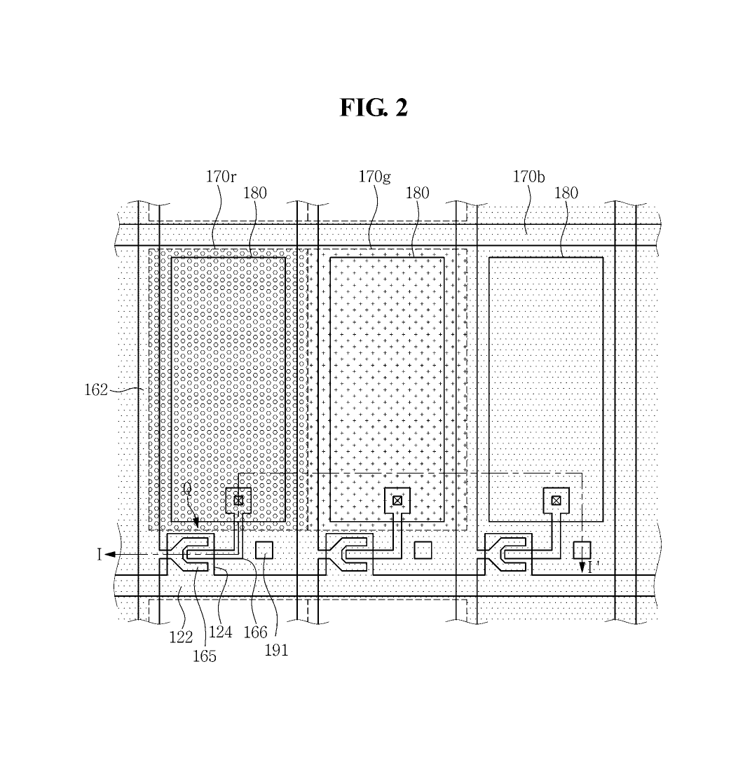

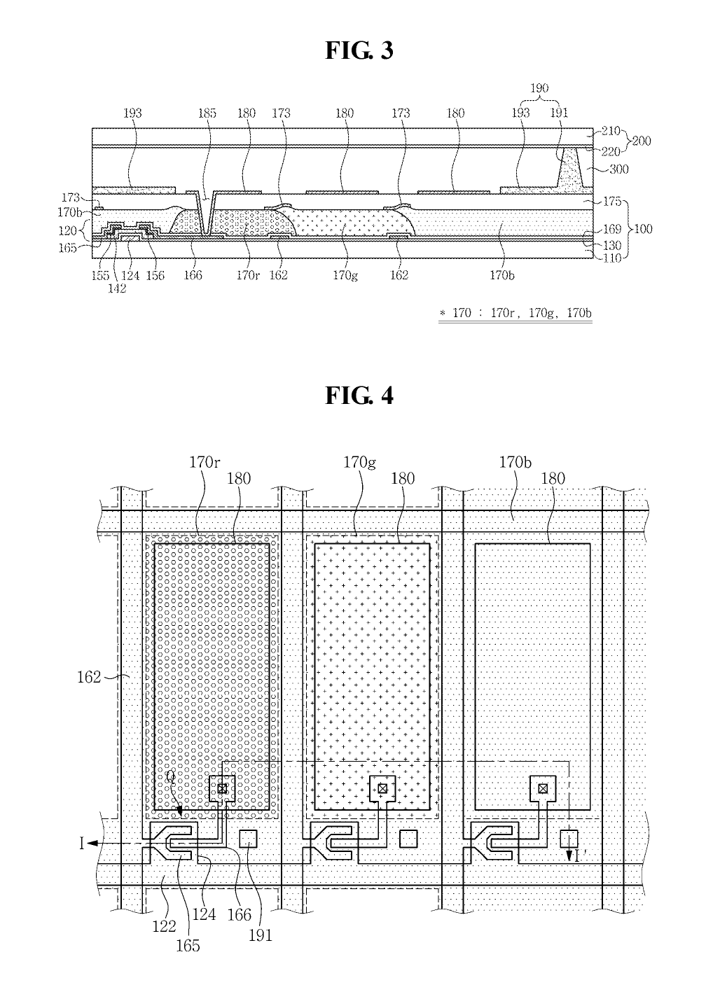

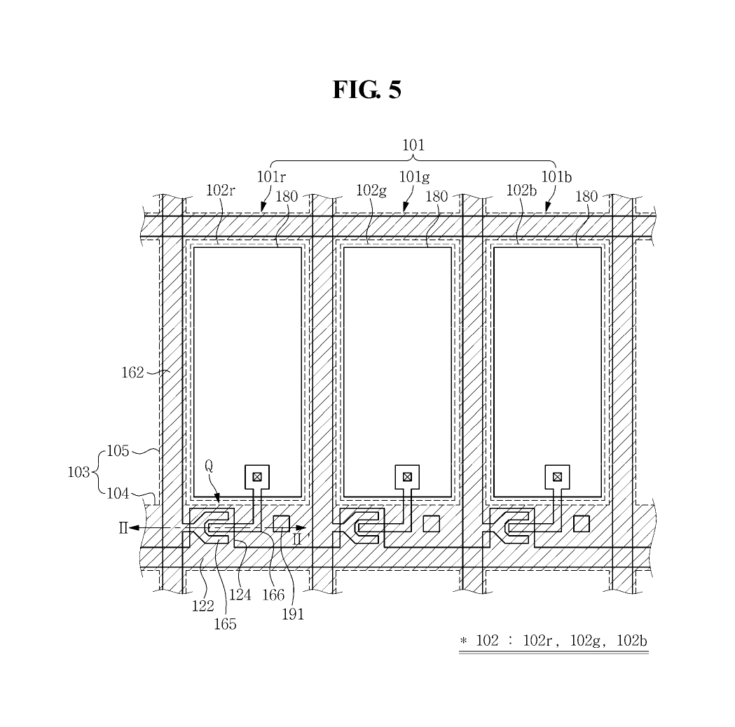

FIG. 1 is a schematic plan view illustrating a display device according to an exemplary embodiment. FIG. 2 is a schematic plan view illustrating color filters according to an exemplary embodiment. FIG. 3 is a cross-sectional view taken along line I-I′ of FIG. 1. FIG. 4 is a schematic plan view illustrating color filters according to another exemplary embodiment.

Referring to FIGS. 1, 2, and 3, a display device according to an exemplary embodiment includes: a lower panel 100, an upper panel 200 opposed to the lower panel 100, and a liquid crystal layer 300 interposed between the lower panel 100 and the upper panel 200.

The lower panel 100 includes: a lower substrate 110 in which a plurality of pixel units 101 including red, green, and blue pixel units 101r, 101g, and 101b are arranged in a matrix form; a layer structure 120 disposed on the lower substrate 110 and including a thin film transistor Q; a plurality of color filters 170 disposed on the layer structure 120 and including red, green, and blue color filters 170r, 170g, and 170b, a planarization layer 175 on the plurality of color filters 170, and a pixel electrode 180 and a light shielding member 190 on the planarization layer 175.

The red, green, and blue pixel units 101r, 101g, and 101b may respectively include: pixel regions 102r, 102g, and 102b in which the pixel electrode 180 is disposed; a first light shielding area 104 on which the gate line 122 and the thin film transistor Q are disposed; and a second light shielding area 105 on which the data line 162 is disposed.

Hereinafter, for ease of description, the red, green, and blue pixel regions 102r, 102g, and 102b are collectively referred to as a pixel region 102; and the first light shielding area 104 and the second light shielding area 105 are collectively referred to as a light shielding area 103.

The pixel region 102 refers to an area through which light supplied from a backlight unit (not illustrated) may be or may not be transmitted outwards according to an alignment of liquid crystal molecules of the liquid crystal layer 300; and the light shielding area 103 is an area at which light supplied from the backlight unit is prevented from being transmitted outwards.

The lower substrate 110 may include an insulating substrate formed of transparent glass such as soda lime glass or borosilicate glass, plastic, or the like.

Gate wirings 122 and 124 configured to transmit a gate signal are disposed on the lower substrate 110. The gate wirings 122 and 124 may include a gate line 122 extending in a direction, for example, a horizontal direction, and a gate electrode 124 protruding from the gate line 122 to form a protrusion. The gate electrode 124 may constitute a three-terminal structure of a thin film transistor Q, along with a source electrode 165 and a drain electrode 166 to be described below.

Although not illustrated, a pixel electrode and a storage wiring (not illustrated) for forming a storage capacitor may further be formed on the lower substrate 110. The storage wiring (not illustrated), which is formed together with the gate wirings 122 and 124, may be disposed on the same layer as the gate and may include the same material as that forming the gate wirings 122 and 124. The storage wiring (not shown) and the gate wirings 122 and 124 may be formed through the same process.

The gate wirings 122 and 124 may include aluminum (Al) or alloys thereof, silver (Ag) or alloys thereof, copper (Cu) or alloys thereof, and/or molybdenum (Mo) or alloys thereof, chromium (Cr), tantalum (Ta), and titanium (Ti), and/or the like.

In addition, the gate wirings 122 and 124 may have a multilayer structure including two conductive layers (not illustrated) having different physical properties.

One of the two conductive layers may include a metal having low resistivity, for example, an aluminum (Al)-based metal, a silver (Ag)-based metal, or a copper (Cu)-based metal, such that a signal delay or a voltage drop of the gate wirings 122 and 124 may be reduced.

On the other hand, the other one of the two conductive layers may include a material having an excellent contact property with another material, for example, with indium tin oxide (ITO) and indium zinc oxide (IZO). Examples of such a material may include a molybdenum-based metal, chromium, titanium, tantalum, and the like.

By way of example, the two conductive layers may have a multilayer structure including, such as a chromium lower layer and an aluminum upper layer, an aluminum lower layer and a molybdenum upper layer, and a titanium lower layer and a copper upper layer. However, the present inventive concept is not limited thereto, and the gate wirings 122 and 124 may include various metals and conductive materials.

A gate insulating layer 130 is disposed on the lower substrate 110 and the gate wirings 122 and 124. The gate insulating layer 130 may include silicon oxide (SiOₓ) or silicon nitride (SiNₓ). In addition, the gate insulating layer 130 may further include aluminum oxide, titanium oxide, tantalum oxide, or zirconium oxide.

A semiconductor layer 142 for forming a channel of the thin film transistor Q is disposed on the gate insulating layer 130 to overlap at least the gate electrode 124. The semiconductor layer 142 may be formed of amorphous silicon (hereinafter “a-Si”), poly silicon or an oxide semiconductor including at least one of gallium (Ga), indium (In), tin (Sn), and zinc (Zn).

Ohmic contact layers 155 and 156 are disposed on the semiconductor layer 142. The ohmic contact layers 155 and 156 may be configured to improve a contact property between the semiconductor layer 142 and the source electrode 165 and/or the drain electrode 166 to be described below.

In this regard, the ohmic contact layers 155 and 156 may include amorphous silicon doped with n-type impurities at high concentration (hereinafter, “n+a-Si”). In a case in which the contact property between the semiconductor layer 142 and the source electrode 165 and/or the drain electrode 166 is sufficiently secured, the ohmic contact layers 155 and 156 may be omitted in the present exemplary embodiment.

Data wirings 162, 165, and 166 are disposed on the ohmic contact layers 155 and 156 and the gate insulating layer 130. The data wirings 162, 165, and 166 may include: a data line 162 formed in a direction intersecting the gate line 122, for example, in a longitudinal direction, and defining the pixel unit 101 along with the gate line 122; the source electrode 165 branching off from the data line 162 to extend to an upper portion of the semiconductor layer 142; and the drain electrode 166 formed on the semiconductor layer 142 spaced apart from the source electrode 165 and opposed to the source electrode 165 with respect to the gate electrode 124 or a channel region of the thin film transistor Q. In this regard, the drain electrode 166 may extend from an upper portion of the semiconductor layer 142 to a lower portion of the pixel electrode 180.

A protective layer 169 is disposed over the entire resultant structure formed with the data wirings 162, 165, and 166. The protective layer 169 may have a monolayer or multilayer structure including, for example, silicon oxide, silicon nitride, a photosensitive organic material, or a low dielectric constant insulating material such as a-Si:C:O and a-Si:O:F.

The structure of the thin film transistor Q described hereinabove with reference to FIGS. 1 and 2 is only given by way of example, and the structure of the layer structure 120 including the thin film transistor Q may be susceptible to various modifications and alternatives.

The plurality of color filters 170 including the red color filter 170r, the green color filter 170g, and the blue color filter 170b are disposed on the layer structure 120.

The red color filter 170r and the green color filter 170g may be disposed corresponding to the red pixel region 102r and the green pixel region 102g, respectively.

The blue color filter 170b may be disposed corresponding to the blue pixel region 102b and the first light shielding area 104.

The red color filter 170r and the green color filter 170g may be disposed in an island shape corresponding to the red pixel region 102r and the green pixel region 102g, respectively; and the blue color filter 170b may be disposed in a transverse direction or in a longitudinal direction, corresponding to the blue pixel region 102b and the first light shielding area 104.

The plurality of color filters 170 may be spaced apart from each other in a transverse direction or in a longitudinal direction; but alternatively, edge portions of the color filters 170 disposed adjacent to each other may overlap each other.

Referring to FIG. 4, In some embodiments, the blue color filter 170b may be simultaneously coated over the entire lower substrate 110. The blue color filter 170b on the red pixel region 102r and the green pixel region 102r may be selectively removed through a conventional photolithography using a mask. Thus, the blue color filter 170b may be disposed on a blue pixel region 102b, on the thin film transistor regions of the red pixel region 102r, the green pixel region 102g and the blue pixel region 102g, and on the data line 162. A shielding electrode 170 may be formed on the data line using a conventional photolithography process.

Referring to FIGS. 1, 2, and 3, a shielding electrode 173 may be disposed in the second light shielding area 105 on the plurality of color filters 170. The shielding electrode 173 may be disposed to overlap the data line 162.

The shielding electrode 173 may prevent the visibility of the data line 162 without using an additional light shielding member. That is, light may not be transmitted through the liquid crystal layer 130 that is disposed around the shielding electrode 173. The liquid crystal layer around the shielding electrode 173 is aligned not to transmit light by an electric field between the shielding electrode and the common electrode 220, thereby display black image around the shielding electrode 172 despite the absence of an additional light shielding member. The shielding electrode 173 and the common electrode 220 may have a same potential when the display device is normally black mode, which is to be described below.

The shielding electrode 173 may be disposed to extend along the data line 162, and may have a width greater than that of the data line 162.

The shielding electrode 173 is disposed in the second light shielding area 105. The shielding electrode 173 may prevent light supplied from a backlight unit (not illustrated) from being directed outwards, and prevent externally incident light from being irradiated on the data line 162.

The planarization layer 175 may be disposed on the plurality of color filters 170 formed with the shielding electrodes 173. The planarization layer 175 may have a monolayer or multilayer structure including, for example, silicon oxide, silicon nitride, a photosensitive organic material, or a low dielectric constant insulating material such as a-Si:C:O or a-Si:O:F.

A contact hole 185 may be formed on the protective layer 169, the color filter 170, and the planarization layer 175 to expose therethrough a part of the drain electrode 166, for example, an end portion of the drain electrode 166 disposed below the pixel electrode 180.

The pixel electrode 180 is disposed on the planarization layer 175 to be electrically connected to the drain electrode 166 through the contact hole 185. The pixel electrode 180 may include a transparent conductive material, such as indium tin oxide (ITO) and indium zinc oxide (IZO). As described hereinabove, the pixel electrode 180 may be disposed in the pixel region 102.

The light shielding member 190 is disposed in the first light shielding area 104 on the planarization layer 175. The light shielding member 190 may be disposed to correspond to the first light shielding area 104 extending parallel to the gate line 122.

The light shielding member 190 may be disposed in the first light shielding area 104 to prevent light supplied from the backlight unit (not illustrated) from being directed outwards and to further prevent externally incident light from being irradiated on the gate line 122 and on the thin film transistor Q. The light shielding member 190 may not overlap the pixel electrode 180 disposed in the pixel region 102. However, the light shielding member 190 may overlap edges of the pixel electrode 180 disposed in the pixel region 102.

The light shielding member 190 may include a column spacer 191 protruding from a peripheral portion 193, that is, a part other than the column spacer 191. In other words, a portion of the light shielding member 190, protruding relative to the peripheral portion 193, is referred to as the column spacer 191. The column spacer 191 may maintain a gap between the lower panel 100 and the upper panel 200 uniformly, thereby improving an overall operation property of the LCD device.

The light shielding member 190 may include a negative or positive photoresist, a black pigment, a black resin, or the like.

Although not illustrated, a lower alignment layer may be disposed on the pixel electrode 180 and the light shielding member 190. The lower alignment layer may be a homeotropic alignment layer and may include a photoreactive material.

The lower alignment layer may include one of polyamic acid, polysiloxane, and polyimide.

The upper panel 200 may include an upper substrate 210 and the common electrode 220. The upper substrate 210 may include an insulating substrate formed of transparent materials, such as glass and plastics. The common electrode 220 may be formed of a transparent conductive material such as indium tin oxide (ITO), indium zinc oxide (IZO), or the like.

Although not illustrated, the upper panel 200 may further include an upper alignment layer. The upper alignment layer may be disposed on the common electrode 220. The upper alignment layer may include a material the same as that forming the lower alignment layer.

When surfaces of the lower substrate 110 and the upper substrate 210 facing each other are respectively defined as upper surfaces of the corresponding substrate, and surfaces opposite to the upper surfaces are respectively defined as lower surfaces of the corresponding substrate, an upper polarizer may further be disposed on a lower surface of the upper substrate 210, and a lower polarizer may further be disposed on a lower surface of the lower substrate 110.

The liquid crystal layer 300 may include a nematic liquid crystal material having a positive dielectric anisotropy. Within the liquid crystal layer 300, the liquid crystal molecules may be aligned to have a structure in which a major axis thereof lies parallel to one of the lower panel 100 and the upper panel 200, and the direction thereof is spirally twisted 90 degrees from a rubbing direction of the alignment layer in the lower panel 100 to the upper panel 200. In addition, the liquid crystal layer 300 may include a homeotropic liquid crystal material.

In the display device according to an exemplary embodiment, the blue color filter is disposed in the first light shielding area on which the thin film transistor and the like are disposed, such that light shielding property of the light shielding area may be improved.

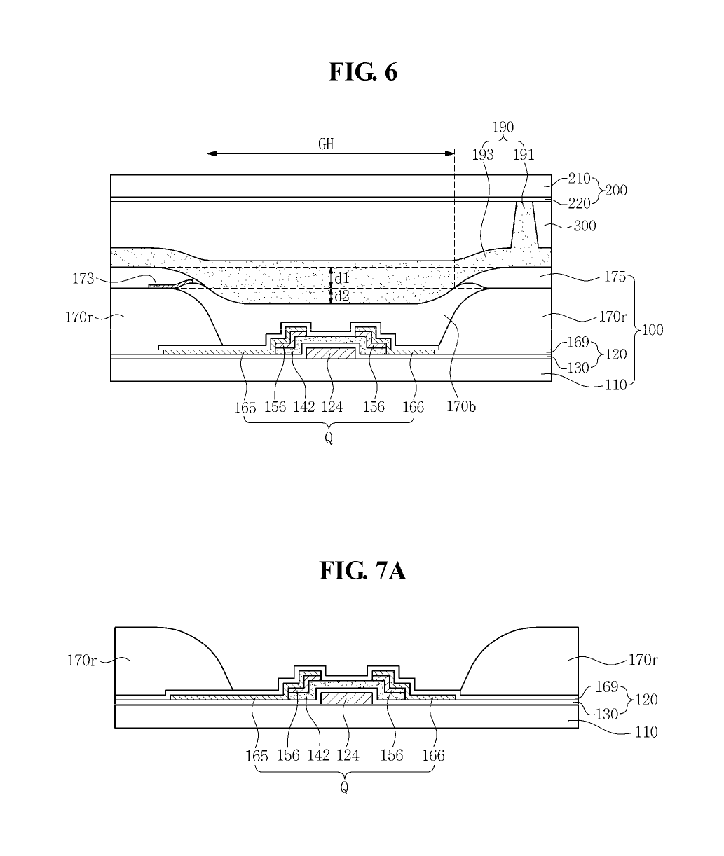

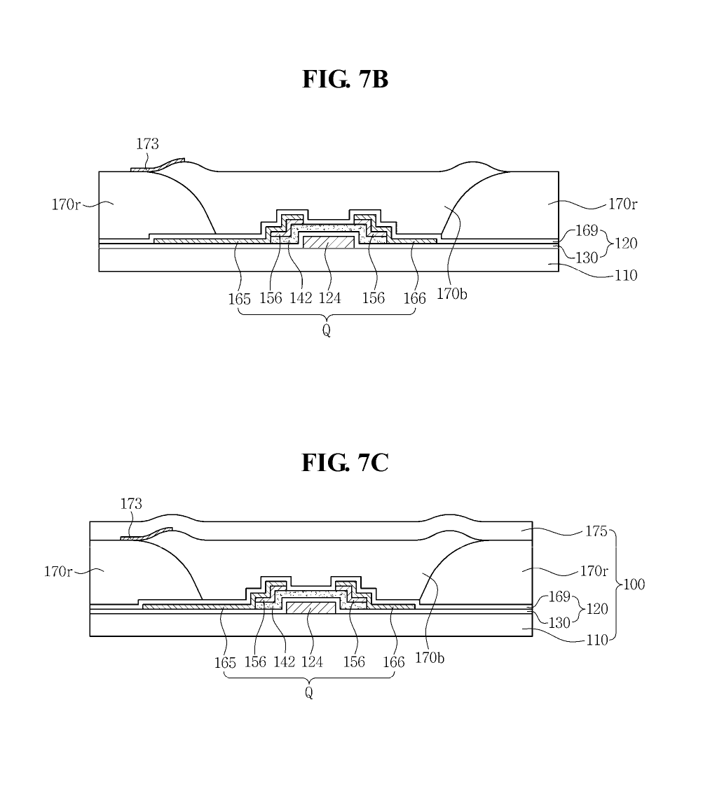

FIG. 5 is a schematic plan view illustrating a display device according to another exemplary embodiment; and FIG. 6 is a cross-sectional view taken along line II-II′ of FIG. 5. Among descriptions of another exemplary embodiment, the repeated description described hereinabove based on one exemplary embodiment will be omitted.

Referring to FIGS. 5 and 6, a display device according to another exemplary embodiment includes: a lower panel 100, an upper panel 200 opposed to the lower panel 100, and a liquid crystal layer 300 interposed between the lower panel 100 and the upper panel 200.

The lower panel 100 includes: a lower substrate 110 on which a plurality of pixel units 101 including red, green, and blue pixel units 101r, 101g, and 101b are arranged in a matrix form; a layer structure 120 disposed on the lower substrate 110 and including a thin film transistor Q; a plurality of color filters 170 disposed on the layer structure 120 and including red, green, and blue color filters 170r, 170g, and 170b; a planarization layer 175 disposed on the plurality of color filters 170; and a pixel electrode 180 and a light shielding member 190 disposed on the planarization layer 175.

The red, green, and blue pixel units 101r, 101g, and 101b may respectively include pixel regions 102r, 102g, and 102b disposed with the pixel electrodes 180, a first light shielding area 104 disposed with the gate line 122 and the thin film transistor Q, and a second light shielding area 105 disposed with the data line 162.

Hereinafter, for ease of description, the red, green, and blue pixel regions 102r, 102g, and 102b are collectively referred to as a pixel region 102; and the first light shielding area 104 and the second light shielding area 105 are collectively referred to as a light shielding area 103. A plurality of color filters 170 may be disposed on the layer structure 120 that includes the red color filter 170r, the green color filter 170g, and the blue color filter 170b.

The red color filter 170r and the green color filter 170g may be disposed corresponding to the red pixel unit 101r and the green pixel unit 101g, respectively.

The blue color filter 170b may be disposed on the blue pixel unit 101b and on at least a part of the first light shielding areas 104 of the red pixel unit 101r and the green pixel unit 101g. In particular, the blue color filter 170b may be disposed on the thin film transistors Q of the red pixel unit 101r and the green pixel unit 101g.

Meanwhile, subsequent to the formation of the planarization layer 175 on the plurality of color filters 170, an aperture is formed on a part of the planarization layer 175, in order to prevent bubble generation caused by outgassing. Herein, such an aperture is referred to as a degassing hole GH.

In the display device according to another exemplary embodiment, the degassing hole GH may be formed on the thin film transistor Q. In order to form the degassing hole GH, a dry etching process may be generally performed, during which a static electricity may be generated, resulting in removal of the planarization layer 175 along with the removal of a partial surface of the color filter 170 disposed under the planarization layer 175.

Accordingly, the color filter 170 of the thin film transistor Q may have a height difference with respect to the color filter 170 disposed therearound.

A light shielding member 190 is disposed in the first light shielding area 104 on the resultant structure formed with the degassing hole. The light shielding member 190 disposed on the thin film transistor Q may have a thickness greater than that of the light shielding member 190 disposed therearound.

By way of example, based on the assumption that a thickness d1 of the planarization layer 175 is in a range of about 3000 Å to about 3500 Å, and a thickness d2 of the blue color filter 170b, which is recessed due to the etching process, is in a range of about 3000 Å to about 5000 Å, and the planarizing capability of the light shielding member 190 is about 70%, the light shielding member 190 disposed on the blue color filter 170b on the thin film transistor Q may have a thickness greater than a peripheral portion thereof by about 4000 Å to about 6500 Å.

In addition, the color filter 170 disposed on the thin film transistor Q may be directly in contact with the light shielding member 190. Since the color filter 170 disposed on the thin film transistor Q is a blue color filter 170b, the blue color filter 170b may be directly in contact with the light shielding member 190.

In the display device according to another exemplary embodiment, the blue color filter 170b is disposed on the thin film transistor Q and the degassing hole GH is formed on the thin film transistor Q, thereby achieving an increase in thickness of the light shielding member 190 disposed thereon. Accordingly, the light shielding property of the display device may be improved.

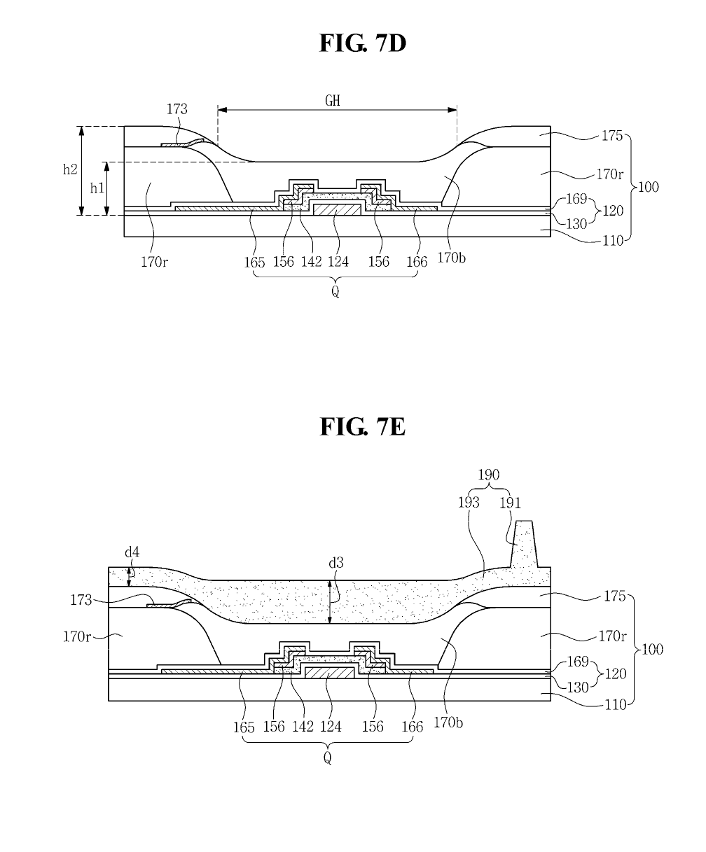

FIGS. 7A through 7E are cross-sectional views illustrating a method of manufacturing a display device according to another exemplary embodiment. FIGS. 7A through 7E are cross-sectional views illustrating a light shielding area of a red pixel unit 101r.

Referring to FIG. 7A, a red color filter 170r is coated on a lower substrate 110 formed with a thin film transistor Q. The red color filter 170r on the thin film transistor Q may be removed. The red color filter 170r may be coated over the entire lower substrate 110, and the red color filter 170r on the thin film transistor Q and other pixel region, for example, the green pixel region 102g and the blue pixel region 102b may be removed through a conventional photolithography using a mask.

Referring to FIG. 7B, the blue color filter 170b may be coated on the thin film transistor Q of the red pixel unit 101r. The blue color filter 170b may be spaced apart from the red color filter 170r disposed adjacent thereto; but alternatively, edge portions thereof disposed adjacent to each other may overlap each other.

The color filter including the red color filter 170r and the blue color filter 170b may be formed through a photolithography process, an inkjet process, or the like, other than being coated using a mask.

Referring to FIG. 7C, a planarization layer 175 may be formed on the shielding electrode 170, the red color filter 170r and the blue color filter 170b. The planarization layer 175 may include silicon oxide or silicon nitride. The planarization layer 175 may be formed to have a thickness in a range of about 3000 Å to about 3500 Å.

Referring to FIG. 7D, a degassing hole GH may be formed on the blue color filter 170b and the planarization layer 175 disposed on the thin film transistor Q. The degassing hole GH may be defined by forming an aperture in a part of the blue color filter 170b and the planarization layer 175 through a dry etching process.

Due to the dry etching process to form the degassing hole GH, a partial surface of the blue color filter 170b and the planarization layer 175 disposed on the blue color filter 170b may be removed. Accordingly, a height h1 of an area on which the thin film transistor Q is formed is less than a height h2 of a peripheral portion thereof.

Referring to FIG. 7E, a light shielding member 190 may be formed on the resultant structure formed with the degassing hole GH. A column spacer 191 and a peripheral portion 193, that is, a part other than the column spacer 191, may be simultaneously formed to each have different heights, thereby forming the light shielding member 190.

In this regard, the light shielding member 190 disposed on an area formed with the thin film transistor Q may have a thickness d3 greater than a thickness d4 of a peripheral portion thereof.

From the foregoing, it will be appreciated that various embodiments in accordance with the present disclosure have been described herein for purposes of illustration, and that various modifications may be made without departing from the scope and spirit of the inventive concept. Accordingly, the various exemplary embodiments disclosed herein are not intended to be limiting of the true scope and spirit of the inventive concept. Various features of the above described and other exemplary embodiments can be mixed and matched in any manner, to produce further exemplary embodiments consistent with the inventive concept.

What is claimed is:

1. A display device comprising:
a lower substrate comprising red, green, and blue pixel regions and a light shielding area;
an upper substrate opposed to the lower substrate;
a liquid crystal layer between the lower substrate and the upper substrate;
a gate line and a data line on the lower substrate;
a thin film transistor connected to the gate line and the data line;
red, green, and blue color filters on the thin film transistor; and
a pixel electrode on the red, green, and blue color filters in the pixel region,
wherein the light shielding area comprises a first light shielding area disposed with the gate line and the thin film transistor and a second light shielding area disposed with the data line,
wherein the red and green color filters are disposed in the red and green pixel regions, respectively, and
wherein the blue color filter is disposed in the blue pixel region and in the first light shielding area.

2. The display device of claim 1, further comprising a light shielding member disposed on the blue color filter in the first light shielding area.

3. The display device of claim 2, wherein the light shielding member comprises a column spacer and a peripheral portion, that is, a part other than the column spacer.

4. The display device of claim 2, wherein the blue color filter disposed on the thin film transistor is directly in contact with the light shielding member.

5. The display device of claim 2, wherein the light shielding member disposed on the thin film transistor has a thickness greater than a thickness of the light shielding member disposed on a peripheral portion of the thin film transistor.

6. The display device of claim 1, further comprising a shielding electrode disposed on the red, green, and blue color filters and overlapping the data line.

7. The display device of claim 6, wherein the shielding electrode extends along the data line.

8. A display device comprising:
a lower substrate comprising red, green, and blue pixel units;
an upper substrate opposed to the lower substrate;
a liquid crystal layer disposed between the lower substrate and the upper substrate;
a gate line and a data line on the lower substrate;
a thin film transistor connected to the gate line and the data line;
red, green, and blue color filters on the thin film transistor; and
a pixel electrode on the red, green, and blue color filters,
wherein red, green, and blue pixel units respectively comprise a pixel region disposed with the pixel electrode, a first light shielding area disposed with the gate line and the thin film transistor, and a second light shielding area disposed with the data line,
wherein the red and green color filters are disposed on the red and green pixel units, and
wherein the blue color filter is disposed on the blue pixel unit and in at least a part of each corresponding first light shielding area of the red and green pixel units.

9. The display device of claim 8, wherein the at least a part of each corresponding first light shielding area of the red and green pixel units is disposed on the thin film transistor of the red and green pixel units.

10. The display device of claim 9, wherein the blue color filter disposed on the thin film transistor is directly in contact with the light shielding member.

11. The display device of claim 9, wherein the light shielding member disposed on the thin film transistor has a thickness greater than a thickness of the light shielding member disposed on a peripheral portion of the thin film transistor.

12. The display device of claim 8, further comprising a light shielding member disposed on the red, green, and blue color filters in the first light shielding area.

13. The display device of claim 8, wherein the light shielding member comprises a column spacer and a peripheral portion, that is, a part other than the column spacer.

14. The display device of claim 8, further comprising a shielding electrode disposed on the red, green, and blue color filters and overlapping the data line.

15. The display device of claim 14, wherein the shielding electrode extends along the data line.

16. A method of manufacturing a display device comprising:
forming a thin film transistor in a light shielding area corresponding to red, green, and blue pixel regions on a lower substrate;
forming red and green color filters on the thin film transistor corresponding to the red and green pixel regions;
forming a blue color filter on the thin film transistor in the blue pixel region and in the light shielding area corresponding to red, green, and blue pixel regions;
forming a planarization layer on the red, green, and blue color filters; and
forming a light shielding member on the planarization layer in the light shielding area.

17. The method of claim 16, wherein the forming of the light shielding member further comprises: forming a degassing hole on the planarization layer disposed on the thin film transistor.

18. The method of claim 16, wherein the light shielding member disposed on the thin film transistor has a thickness greater than a thickness of the light shielding member disposed on a peripheral portion of the thin film transistor.

19. The method of claim 16, wherein the forming of the light shielding member comprises: simultaneously forming a column spacer and a pheripheral portion, that is, a part other than the column spacer, to each have different heights.
